(19) United States
(12) Patent Application Publication
(10) Pub. No.: US 2024/0040844 A1
(43) Pub. Date: Feb. 1, 2024

(54) DISPLAY DEVICE AND ELECTRONIC DEVICE

(71) Applicants: SONY GROUP CORPORATION, TOKYO (JP); SONY SEMICONDUCTOR SOLUTIONS CORPORATION, KANAGAWA (JP)

(72) Inventors: HIROKO SUSA, TOKYO (JP); TAKEO TSUKAMOTO, TOKYO (JP); MIKI KIMIJIMA, TOKYO (JP); AKIRA WATANABE, KANAGAWA (JP)

(21) Appl. No.: 18/256,616

(22) PCT Filed: Dec. 22, 2021
(86) PCT No.: PCT/JP2021/047535

§ 371 Date: Jun. 8, 2023

(30) Foreign Application Priority Data
Dec. 22, 2020 (JP) 2020-212887

(51) Int. Cl. H10K 59/122; H10K 50/15

(52) U.S. Cl. CPC H10K 59/122; H10K 50/15; H10K 2101/30

(57) ABSTRACT

There is provided a display device capable of preventing leakage of a drive current generated between adjacent subpixels. A display device including a first electrode layer having a plurality of electrodes arranged two-dimensionally, a second electrode layer provided to face the first electrode layer, an electroluminescence layer provided between the first electrode layer and the second electrode layer, and an insulating layer provided between the electrodes adjacent to each other. The electroluminescence layer includes a hole transport layer, and the hole transport layer is adjacent to the insulating layer. An energy level E_{interface(1)} at an interface between the insulating layer and the hole transport layer and an energy level E_{bulk(1)} in a bulk of the hole transport layer satisfy the following Formula (1).

### TECHNICAL FIELD

The present disclosure relates to a display device and an electronic device including the display device.

### BACKGROUND ART

In recent years, as an organic electroluminescence (EL) display device (hereinafter simply referred to as a “display device”), a device having an organic layer common to all subpixels has been proposed. However, in the display device having such a configuration, leakage of a drive current is likely to occur between adjacent subpixels. Accordingly, a technology for preventing leakage of a drive current between adjacent subpixels has been proposed (see, for example, Patent Document 1).

### CITATION LIST

### Patent Document

Patent Document 1: WO 2020/111202 Pamphlet

### SUMMARY OF THE INVENTION

### Problems to be Solved by the Invention

As described above, in recent years, in a display device having an organic EL layer common to all subpixels, a technology for preventing leakage of a drive current generated between adjacent subpixels is desired.

An object of the present disclosure is to provide a display device capable of preventing leakage of a drive current generated between adjacent subpixels, and an electronic device including the display device.

### Solutions to Problems

In order to achieve the above-described object, a first disclosure is a display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer, the hole transport layer being adjacent to the insulating layer, and
an energy level E_{interface(1)} at an interface between the insulating layer and the hole transport layer and an energy level E_{bulk(1)} in a bulk of the hole transport layer satisfy the following Formula (1).

0≤E_{bulk(1)}−E_{interface(1)}≤0.3 eV (1)

A second disclosure is a display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer,
the hole transport layer includes at least a first hole transport layer and a second hole transport layer, the first hole transport layer being adjacent to the insulating layer, and
an energy level E_{bulk(2a)} of a bulk of the first hole transport layer and an energy level E_{bulk(2b)} of a bulk of the second hole transport layer satisfy the following Formula (2).

0≤E_{bulk(2b)}−E_{bulk(2a)}≤0.3 eV (2)

A third disclosure is a display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer and a hole injection layer, the hole injection layer being adjacent to the insulating layer, and
an energy level E_{interface(3)} at an interface between the hole injection layer and the hole transport layer and an energy level E_{bulk(3)} in a bulk of the hole transport layer satisfy the following Formula (3).

0≤E_{bulk(3)}−E_{interface(3)}≤0.3 eV (3)

A fourth disclosure is a display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer and a hole injection layer, the hole injection layer being adjacent to the insulating layer,
the hole transport layer includes at least a first hole transport layer and a second hole transport layer, the first hole transport layer being adjacent to the hole injection layer, and
an energy level E_{bulk(4a)} of a bulk of the first hole transport layer and an energy level E_{bulk(4b)} of a bulk of the second hole transport layer satisfy the following Formula (4).

0≤E_{bulk(4b)}−E_{bulk(4a)}≤0.3 eV (4)

### BRIEF DESCRIPTION OF DRAWINGS

FIG. 1 is a schematic diagram illustrating an example of an overall configuration of a display device according to a first embodiment of the present disclosure.

FIG. 2 is a cross-sectional view illustrating an example of a configuration of the display device according to the first embodiment of the present disclosure.

FIG. 3 is a cross-sectional view illustrating an example of a configuration of an organic EL layer.

FIG. 4A is a diagram illustrating an example of an energy diagram in a case where a relationship of E_{bulk(1)}−E_{interface(1)}≤0.3 eV is satisfied. FIG. 4B is a diagram illustrating an example of an energy diagram in a case where the relationship of E_{bulk(1)}−E_{interface(1)}≤0.3 eV is not satisfied.

FIG. 5 is a cross-sectional view illustrating an example of a configuration of a display device according to a second embodiment of the present disclosure.

FIG. 6A is a diagram illustrating an example of an energy diagram in a case where a relationship of E_{bulk(2b)}−E_{bulk(2a)}≤0.3 eV is satisfied. FIG. 6B is a diagram illustrating an example of an energy diagram in a case where the relationship of E_{bulk(2b)}−E_{bulk(2a)}≤0.3 eV is not satisfied.

FIG. 7 is a cross-sectional view illustrating an example of a configuration of a display device according to a third embodiment of the present disclosure.

FIG. 8A is a diagram illustrating an example of an energy diagram in a case where a relationship of E_{bulk(3)}−E_{interface(3)}≤0.3 eV is satisfied. FIG. 8B is a diagram illustrating an example of an energy diagram in a case where the relationship of E_{bulk(3)}−E_{interface(3)}≤0.3 eV is not satisfied.

FIG. 9 is a cross-sectional view illustrating an example of a configuration of a display device according to a fourth embodiment of the present disclosure.

FIG. 10A is a diagram illustrating an example of an energy diagram in a case where a relationship of E_{bulk(4b)}−E_{bulk(4a)}≤0.3 eV is satisfied. FIG. 10B is a diagram illustrating an example of an energy diagram in a case where the relationship of E_{bulk(4b)}−E_{bulk(4a)}≤0.3 eV is not satisfied.

FIG. 11 is a plan view illustrating an example of a schematic configuration of a module.

FIG. 12A is a front view illustrating an example of an external appearance of a digital still camera. FIG. 12B is a rear view illustrating an example of an external appearance of the digital still camera.

FIG. 13 is a perspective view of an example of an external appearance of a head mounted display.

FIG. 14 is a perspective view illustrating an example of an external appearance of a television apparatus.

FIG. 15 is a graph illustrating a relationship between a difference (E_{HILN}−E_{ILN}) between bond energy E_{HILN} of N1s in a hole injection layer and bond energy E_{ILN} of N1s in an insulating layer and a leakage current between subpixels.

FIG. 16 is a graph illustrating a relationship between a difference between a HOMO of a hole injection layer and a HOMO of an insulating layer, and a hole concentration.

FIG. 17A is a diagram illustrating an example of an energy diagram in a case where leakage can be prevented. FIG. 17B is a diagram illustrating an example of an energy diagram in a case where leakage cannot be prevented.

### MODE FOR CARRYING OUT THE INVENTION

The embodiments of the present disclosure will be described in the following order.
1 First embodiment (example of display device)
2 Second embodiment (example of display device)
3 Third embodiment (example of display device)
4 Fourth embodiment (example of display device)
5 Modification example (modification example of display device)
6 Application example (example of electronic device)

### 1 First Embodiment

### [Configuration of Display Device]

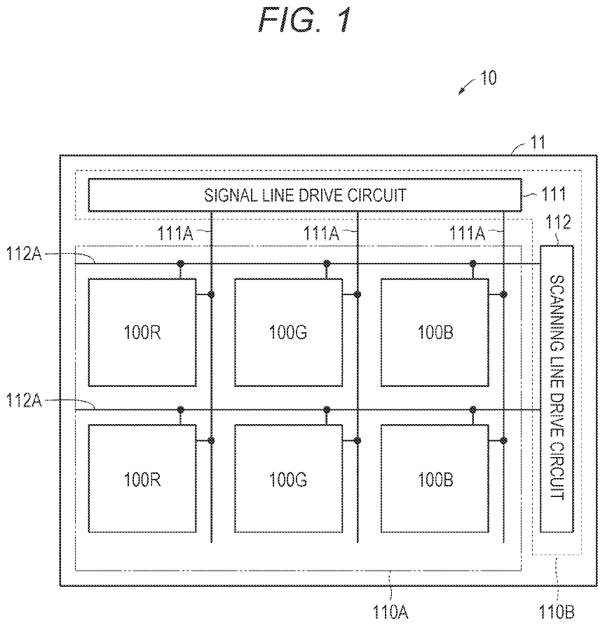

FIG. 1 is a schematic diagram illustrating an example of an overall configuration of a display device 10 according to a first embodiment of the present disclosure. The display device includes a display region 110A and a peripheral region 110B provided on a peripheral edge of the display region 110A. In the display region 110A, a plurality of subpixels 100R, 100G, and 100B is two-dimensionally arranged in a prescribed arrangement pattern such as a matrix.

The subpixel 100R displays red, the subpixel 100G displays green, and the subpixel 100B displays blue. Note that, in the following description, in a case where the subpixels 100R, 100G, and 100B are collectively referred to without being particularly distinguished, they are referred to as subpixels 100. A combination of adjacent subpixels 100R, 100G, and 100B constitutes one pixel (pixel). FIG. 1 illustrates an example in which a combination of three subpixels 100R, 100G, and 100B arranged in a row direction (horizontal direction) constitutes one pixel, but the arrangement of the subpixels 100R, 100G, and 100B is not limited thereto.

In the peripheral region 110B, a signal line drive circuit 111 and a scanning line drive circuit 112, which are drivers for video display, are provided. The signal line drive circuit 111 supplies a signal voltage of a video signal corresponding to luminance information supplied from a signal supply source (not illustrated) to the subpixel 100 selected via the signal line 111A. The scanning line drive circuit 112 includes a shift register or the like that sequentially shifts (transfers) a start pulse in synchronization with an input clock pulse. The scanning line drive circuit 112 scans the subpixels 100 row by row at the time of writing the video signal to each subpixel 100, and sequentially supplies a scanning signal to each scanning line 112A.

The display device 10 may be a microdisplay. The display device 10 may be included in a virtual reality (VR) device, a mixed reality (MR) device, an augmented reality (AR) device, an electronic view finder (EVF), a small projector, or the like.

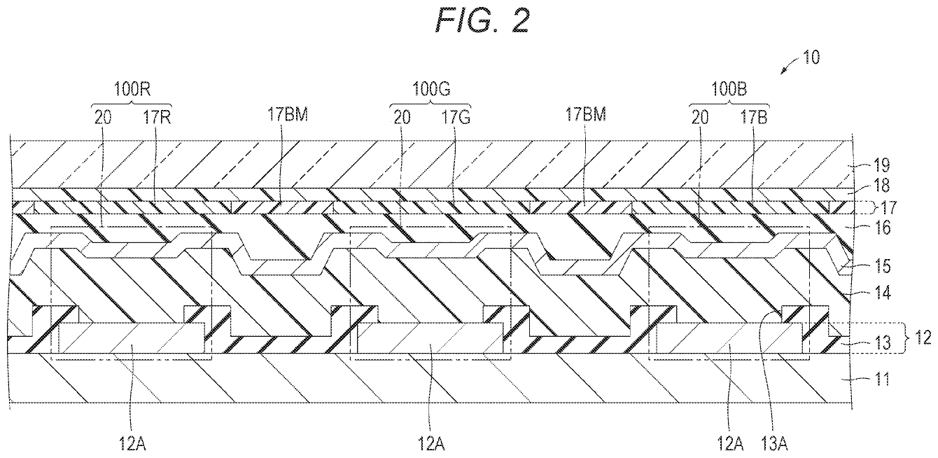

FIG. 2 is a cross-sectional view illustrating an example of a configuration of the display device 10 according to the first embodiment of the present disclosure. The display device 10 includes a drive substrate 11, a first electrode layer 12, an insulating layer 13, an organic EL layer 14, a second electrode layer 15, a protective layer 16, a color filter 17, a filling resin layer 18, and a counter substrate 19.

The display device 10 is an example of a light emitting device. The display device 10 is a top emission type display device. The counter substrate 19 side of the display device 10 is the top side, and the drive substrate 11 side of the display device 10 is the bottom side. In the following description, in each layer constituting the display device 10, a surface on the top side of the display device 10 is referred to as a first surface, and a surface on the bottom side of the display device 10 is referred to as a second surface.

The display device 10 includes a plurality of light emitting elements 20. The plurality of light emitting elements 20 includes the first electrode layer 12, the organic EL layer 14, and the second electrode layer 15. The light emitting element 20 is, for example, a white light emitting element such as a white OLED or a white Micro-OLED (MOLED). As a coloring method in the display device 10, a method using a white light emitting element and the color filter 17 is used.

### (Drive Substrate)

The drive substrate 11 is what is called a backplane, and drives the plurality of light emitting elements 20. The drive substrate 11 is provided with a drive circuit that drives the plurality of light emitting elements 20, a power supply circuit that supplies power to the plurality of light emitting elements 20, and the like (none of which is illustrated).

The substrate body of the drive substrate 11 may be formed by, for example, a semiconductor easily formed with a transistor or the like, or may be formed by glass or resin having low moisture and oxygen permeability. Specifically, the substrate body may be a semiconductor substrate, a glass substrate, a resin substrate, or the like. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

### (First Electrode Layer)

The first electrode layer 12 is provided on the first surface of the drive substrate 11. The first electrode layer 12 is an anode. When a voltage is applied between the first electrode layer 12 and the second electrode layer 15, holes are injected from the first electrode layer 12 into the organic EL layer 14. The first electrode layer 12 also functions as a reflecting layer, and is preferably formed by a material having the highest reflectance and largest work function possible in order to enhance the light emission efficiency. The first electrode layer 12 includes a plurality of electrodes 12A. The plurality of electrodes 12A is electrically separated between the adjacent light emitting elements 20. The plurality of electrodes 12A shares the organic EL layer 14. The plurality of electrodes 12A is two-dimensionally arranged in a prescribed arrangement pattern such as a matrix shape.

The electrode 12A is formed by at least one of a metal layer or a metal oxide layer. More specifically, the electrode 12A is formed by a single layer film of a metal layer or a metal oxide layer, or a stacked film of a metal layer and a metal oxide layer. In a case where the electrode 12A is formed by the stacked film, the metal oxide layer may be provided on the organic EL layer 14 side, or the metal layer may be provided on the organic EL layer 14 side, but from the viewpoint of including a layer having a high work function adjacent to the organic EL layer 14, the metal oxide layer is preferably provided on the organic EL layer 14 side.

The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include AlNd and AlCu.

The metal oxide layer includes, for example, a transparent conductive oxide (TCO). The transparent conductive oxide includes, for example, at least one selected from a group including a transparent conductive oxide including indium (hereinafter referred to as “indium-based transparent conductive oxide”), a transparent conductive oxide including tin (hereinafter referred to as a “tin-based transparent conductive oxide”), and a transparent conductive oxide including zinc (hereinafter referred to as a “zinc-based transparent conductive oxide”).

The indium-based transparent conductive oxide includes, for example, indium tin oxide (ITO), indium zinc oxide (IZO), indium gallium oxide (IGO), or indium gallium zinc oxide (IGZO) fluorine-doped indium oxide (IFO). Among these transparent conductive oxides, the indium tin oxide (ITO) is particularly preferable. This is because the indium tin oxide (ITO) has a particularly low hole injection barrier into the organic EL layer 14 as a work function, and thus the drive voltage of the display device 10 can be particularly reduced. The tin-based transparent conductive oxide includes, for example, tin oxide, antimony-doped tin oxide (ATO), or fluorine-doped tin oxide (FTC). The zinc-based transparent conductive oxide includes, for example, zinc oxide, aluminum-doped zinc oxide (AZO), boron-doped zinc oxide, or gallium-doped zinc oxide (GZO).

### (Second Electrode Layer)

The second electrode layer 15 is provided to face the first electrode layer 12. The second electrode layer 15 is provided as an electrode common to all the subpixels 100 in the display region 110A. The second electrode layer 15 is a cathode. When a voltage is applied between the first electrode layer 12 and the second electrode layer 15, electrons are injected from the second electrode layer 15 into the organic EL layer 14. The second electrode layer 15 is a transparent electrode having transparency to light generated in the organic EL layer 14. Here, the transparent electrode also includes a semi-transmissive reflecting layer. The second electrode layer 15 is preferably formed by a material having as high permeability as possible and a small work function in order to enhance luminous efficiency.

The second electrode layer 15 is formed by, for example, at least one of a metal layer or a metal oxide layer. More specifically, the second electrode layer 15 is formed by a single layer film of a metal layer or a metal oxide layer, or a stacked film of a metal layer and a metal oxide layer. In a case where the second electrode layer 15 is formed by a stacked film, the metal layer may be provided on the organic EL layer 14 side, or the metal oxide layer may be provided on the organic EL layer 14 side, but from the viewpoint of including a layer having a low work function adjacent to the organic EL layer 14, the metal layer is preferably provided on the organic EL layer 14 side.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy include an MgAg alloy, an MgAl alloy, an AlLi alloy, and the like. The metal oxide layer includes a transparent conductive oxide. As the transparent conductive oxide, a material similar to the transparent conductive oxide of the electrode 12A described above can be exemplified.

### (EL Layer)

The organic EL layer 14 is provided between the first electrode layer 12 and the second electrode layer 15. The organic EL layer 14 is continuously provided over all the subpixels 100 (that is, the plurality of electrodes 12A) in the display region 110A, and is provided as a layer common to all the subpixels 100 in the display region 110A. The organic EL layer 14 is configured to emit white light.

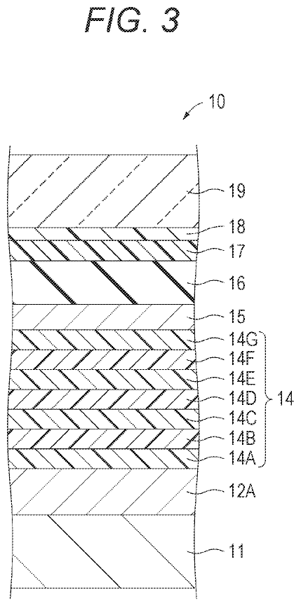

FIG. 3 is a cross-sectional view illustrating an example of a configuration of the organic EL layer 14. The organic EL layer 14 has, for example, a configuration in which a hole transport layer 14A, a red light emitting layer 14B, a light emission separation layer 14C, a blue light emitting layer 14D, a green light emitting layer 14E, an electron transport layer 14F, and an electron injection layer 14G are stacked in this order from the first electrode layer 12 toward the second electrode layer 15.

The hole transport layer 14A is adjacent to the first electrode layer 12 and the insulating layer 13. The hole transport layer 14A is for enhancing hole transport efficiency to each of the light emitting layers 14B, 14D, and 14E. The hole transport layer 14A includes, for example, α-NPD (N,N′-di(1-naphthyl)-N,N′-diphenyl-[1,1′-biphenyl]-4,4′-diamine).

The electron transport layer 14F is for enhancing electron transport efficiency to each of the light emitting layers 14B, 14D, and 14E. The electron transport layer 14F includes, for example, at least one selected from a group including BCP (2,9-dimethyl-4,7-diphenyl-1,10-phenanthroline), Alq3 (aluminum quinolinol complex), Bphen (bathophenanthroline), and the like.

An electron injection layer 17H is for enhancing electron injection from the cathode. The electron injection layer 17H includes, for example, a simple substance of an alkali metal or an alkaline earth metal or a compound including them, specifically, for example, lithium (Li) or lithium fluoride (LiF), or the like.

The light emission separation layer 14C is a layer for adjusting injection of carriers into each of the light emitting layers 14B, 14D, and 14E, and light emission balance of each color is adjusted by injecting electrons or holes into each of the light emitting layers 14B, 14D, and 14E via the light emission separation layer 14C. The light emission separation layer 14C includes, for example, 4,4′-bis[N-(1-naphthyl)-N-phenyl-amino] biphenyl derivative, or the like.

When an electric field is applied to each of the red light emitting layer 14B, the blue light emitting layer 14D, and the green light emitting layer 14E, recombination occurs between holes injected from the electrode 12A and electrons injected from the second electrode layer 15, and red, blue, and green are generated.

The red light emitting layer 14B includes, for example, a red light emitting material. The red light emitting material may be fluorescent or phosphorescent. Specifically, the red light emitting layer 14B includes, for example, a mixture of 4,4-bis(2,2-diphenylvinin) biphenyl (DPVBi) and 2,6-bis[(4′-methoxydiphenylamino)styryl]-1,5-dicyanonaphthalene (BSN).

The blue light emitting layer 14D includes, for example, a blue light emitting material. The blue light emitting material may be fluorescent or phosphorescent. Specifically, the blue light emitting layer 14D includes, for example, a mixture of 4,4′-bis[2-{4-(N,N-diphenylamino)phenyl}vinyl] biphenyl (DPAVBi) with DPVBi.

The green light emitting layer 14E includes, for example, a green light emitting material. The green light emitting material may be fluorescent or phosphorescent. Specifically, the green light emitting layer 14E includes, for example, a mixture of DPVBi and coumarin 6.

### (Insulating Layer)

The insulating layer 13 is provided on the first surface of the drive substrate 11 and between the adjacent electrodes 12A. The insulating layer 13 insulates the separated electrodes 12A from each other. The insulating layer 13 has a plurality of openings 13A. Each of the plurality of openings 13A is provided corresponding to each subpixel 100. More specifically, each of the plurality of openings 13A is provided on the first surface (the surface facing the second electrode layer 15) of each of the separated electrodes 12A. The electrode 12A and the organic EL layer 14 are in contact with each other through the opening 13A.

The insulating layer 13 may be an organic insulating layer, an inorganic insulating layer, or a stack thereof. The organic insulating layer includes, for example, at least one selected from a group including a polyimide-based resin, an acrylic resin, a novolac-based resin, and the like. The inorganic insulating layer includes, for example, at least one selected from a group including silicon oxide (SiOₓ), silicon nitride (SiNₓ), silicon oxynitride (SiOₓN_{y}), and the like.

### (Protective Layer)

The protective layer 16 is provided on the first surface of the second electrode layer 15 and covers the plurality of light emitting elements 20. The protective layer 16 shields the light emitting element 20 from the outside air, and prevents moisture infiltration into the light emitting element 20 from the external environment. Furthermore, in a case where the second electrode layer 15 is formed by a metal layer, the protective layer 16 may have a function of preventing oxidation of the metal layer.

The protective layer 16 includes, for example, an inorganic material or a polymer resin having low hygroscopicity. The protective layer 16 may have a single-layer structure or a multilayer structure. In a case where the thickness of the protective layer 16 is increased, it is preferable to have a multilayer structure. This is to alleviate the internal stress in the protective layer 16. The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin includes, for example, at least one selected from a group including a thermosetting resin, an ultraviolet curable resin, and the like.

### (Color Filter)

The color filter 17 is provided on the first surface of the protective layer 16. The color filter 17 is, for example, an on-chip color filter (OCCF). The color filter 17 includes, for example, a red filter 17R, a green filter 17G, and a blue filter 17B. Each of the red filter 17R, the green filter 17G, and the blue filter 17B is provided to face the light emitting element 20. The red filter 17R and the light emitting element 20 constitute the subpixel 100R, the green filter 17G and the light emitting element 20 constitute the subpixel 100G, and the blue filter 17B and the light emitting element 20 constitute the subpixel 100B.

White light emitted from the light emitting elements 20 in the subpixels 100R, 100G, and 100B is transmitted through the red filter 17R, the green filter 17G, and the blue filter 17B described above, so that red light, green light, and blue light are each emitted from the display surface. Furthermore, a light shielding layer 17BM may be provided between the color filters 17R, 17G, and 17B, that is, in a region between the subpixels 100. Note that the color filter 17 is not limited to the on-chip color filter, and may be provided on the second surface of the counter substrate 19 (the surface facing the organic EL layer 14).

### (Filling Resin Layer)

The filling resin layer 18 is provided between the color filter 17 and the counter substrate 19. The filling resin layer 18 has a function as an adhesive layer for bonding the color filter 17 and the counter substrate 19. The filling resin layer 18 includes, for example, at least one selected from a group including a thermosetting resin, an ultraviolet curable resin, and the like.

### (Counter Substrate)

The counter substrate 19 is provided to face the drive substrate 11. More specifically, the counter substrate 19 is provided such that the second surface of the counter substrate 19 and the first surface of the drive substrate 11 face each other. The counter substrate 19 and the filling resin layer 18 seal the light emitting element 20, the color filter 17, and the like. The counter substrate 19 includes a material such as glass transparent to each color light emitted from the color filter 17.

### (Relationship of Energy Ranking)

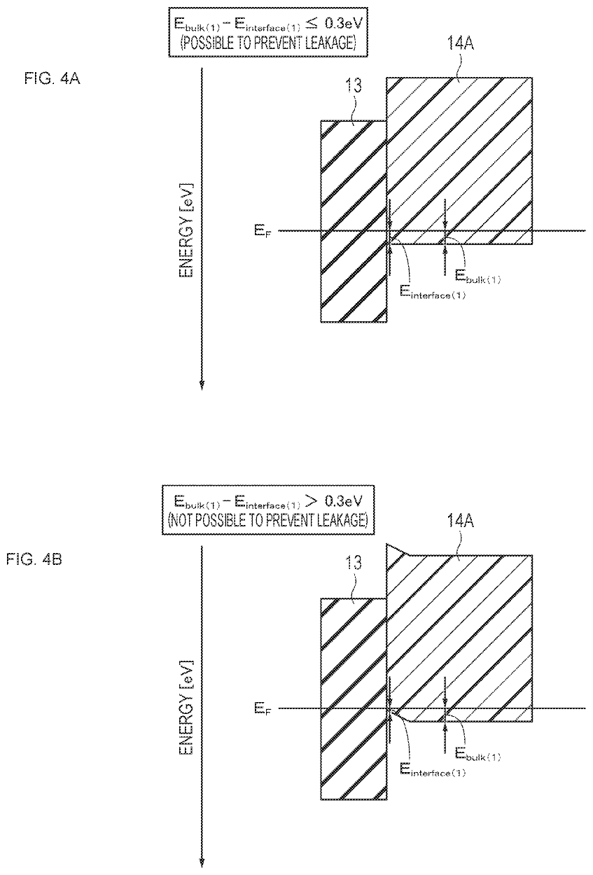

FIG. 4A is a diagram illustrating an example of an energy diagram of the insulating layer 13 and the hole transport layer 14A. An energy level E_{interface(1)} at the interface between the hole transport layer 14A and the insulating layer 13 and an energy level E_{bulk(1)} in a bulk of the hole transport layer 14A satisfy the following Formula (1).

0≤E_{bulk(1)}−E_{interface(1)}≤0.3 eV (1)

In order to control band bending of the hole transport layer 14A so as to satisfy the above Formula (1), it is only required to control the positional relationship of the Fermi level between the insulating layer 13 and the hole transport layer 14A.

The energy level E_{interface(1)} described above is measured as follows. Each layer formed on the first surface of the organic EL layer 14 is removed. After the removal, the organic EL layer 14 is etched from the interface between the insulating layer 13 and the hole transport layer 14A to a position of 2 nm on the hole transport layer 14A side by ion sputtering. Subsequently, an energy level (highest occupied molecular orbital (HOMO)) of the surface exposed by etching is measured by X-ray photoelectron spectroscopy (XPS), and the measured value is defined as the energy level E_{interface(1)}. The measurement conditions of XPS are as follows.
XPS apparatus: Quantum 2000 manufactured by ULVAC-PHI
Radiation source: Al Kα ray 1486.6 eV
Beam diameter: 100 μm
Emission angle: 90 degrees

The energy level E_{bulk(1)} described above is measured as follows. Each layer formed on the first surface of the organic EL layer 14 is removed. After the removal, the organic EL layer 14 is etched from the interface between the insulating layer 13 and the hole transport layer 14A to a position of 10 nm on the hole transport layer 14A side by ion sputtering. Subsequently, the energy level (HOMO) of the surface exposed by etching is measured by XPS, and the measured value is defined as the energy level E_{bulk(1)}. The measurement conditions of XPS are similar to those of the method of measuring the energy level E_{interface(1)} described above.

### [Method of Manufacturing Display Device]

Hereinafter, an example of a method of manufacturing the display device 10 according to the first embodiment of the present disclosure will be described.

First, a metal layer and a metal oxide layer are sequentially formed on the first surface of the drive substrate 11 by, for example, a sputtering method, and then the metal layer and the metal oxide layer are patterned using, for example, a photolithography technique and an etching technique. Thus, the first electrode layer 12 having the plurality of electrodes 12A is formed.

Next, the insulating layer 13 is formed on the first surface of the drive substrate 11 so as to cover the plurality of electrodes 12A by, for example, a chemical vapor deposition (CVD) method. At this time, for example, by using two types of gases of SiH₄ and NH₃ as process gases and adjusting the flow ratio of these two types of process gases, it is possible to set the energy level E_{interface(1)} and the energy level E_{bulk(1)} to satisfy the above Formula (1). Next, an opening 13A is formed in a portion of the insulating layer 13 located on the first surface of each electrode 12A by, for example, the photolithography technique and the dry etching technique.

Next, the hole transport layer 14A, the red light emitting layer 14B, the light emission separation layer 14C, the blue light emitting layer 14D, the green light emitting layer 14E, the electron transport layer 14F, and the electron injection layer 14G are stacked in this order on the first surface of the plurality of electrodes 12A and the first surface of the insulating layer 13 by, for example, a vapor deposition method, thereby forming the organic EL layer 14. Next, the second electrode layer 15 is formed on the first surface of the organic EL layer 14 by, for example, the vapor deposition method or the sputtering method. Thus, the plurality of light emitting elements 20 is formed on the first surface of the drive substrate 11.

Next, the protective layer 16 is formed on the first surface of the second electrode layer 15 by, for example, the CVD method or the vapor deposition method, and then the color filter 17 is formed on the first surface of the protective layer 16 by, for example, photolithography. Note that, in order to flatten a level difference of the protective layer 16 and a level difference due to a film thickness difference of the color filter 17 itself, a flattening layer may be formed on an upper side, a lower side, or both the upper and lower sides of the color filter 17. Next, the color filter 17 is covered with the filling resin layer 18 using, for example, a one drop fill (ODF) method, and then the counter substrate 19 is placed on the filling resin layer 18. Next, for example, by applying heat to the filling resin layer 18 or irradiating the filling resin layer 18 with ultraviolet rays to cure the filling resin layer 18, the drive substrate 11 and the counter substrate 19 are bonded via the filling resin layer 18. Thus, the display device 10 is sealed. As described above, the display device 10 illustrated in FIG. 2 is obtained.

### [Operation and Effect]

As described above, in the display device 10 according to the first embodiment, as illustrated in FIG. 4A, since the energy level E_{interface(1)} and the energy level E_{bulk(1)} satisfy the above Formula (1), it is possible to prevent leakage of a drive current between the adjacent subpixels 100. On the other hand, as illustrated in FIG. 4B, in a case where the energy level E_{interface(1)} and the energy level E_{bulk(1)} do not satisfy the above Formula (1), leakage of the drive current between the adjacent subpixels 100 cannot be prevented. It is considered that the leakage behavior is caused by formation of a pool of holes due to band bending at the interface between the hole transport layer 14A responsible for hole transport and the insulating layer 13.

### 2 Second Embodiment

### [Configuration of Display Device]

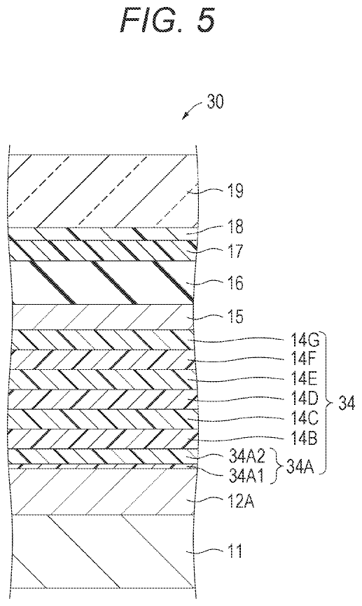

FIG. 5 is a cross-sectional view illustrating an example of a configuration of a display device 30 according to a second embodiment of the present disclosure. The display device 30 is different from the display device 10 according to the first embodiment in that an organic EL layer 34 is provided instead of the organic EL layer 14 (see FIG. 2). Note that, in the second embodiment, same reference numerals are given to parts similar to those of the first embodiment, and the description thereof will be omitted.

The organic EL layer 34 is different from the organic EL layer 14 in the first embodiment in including a hole transport layer 34A having a two-layer structure instead of the hole transport layer 14A having a single-layer structure. The hole transport layer 34A includes a first hole transport layer 34A1 and a second hole transport layer 34A2. The first hole transport layer 34A1 is adjacent to the first electrode layer 12 and the insulating layer 13 (see FIG. 2). The second hole transport layer 34A2 is adjacent to the red light emitting layer 14B.

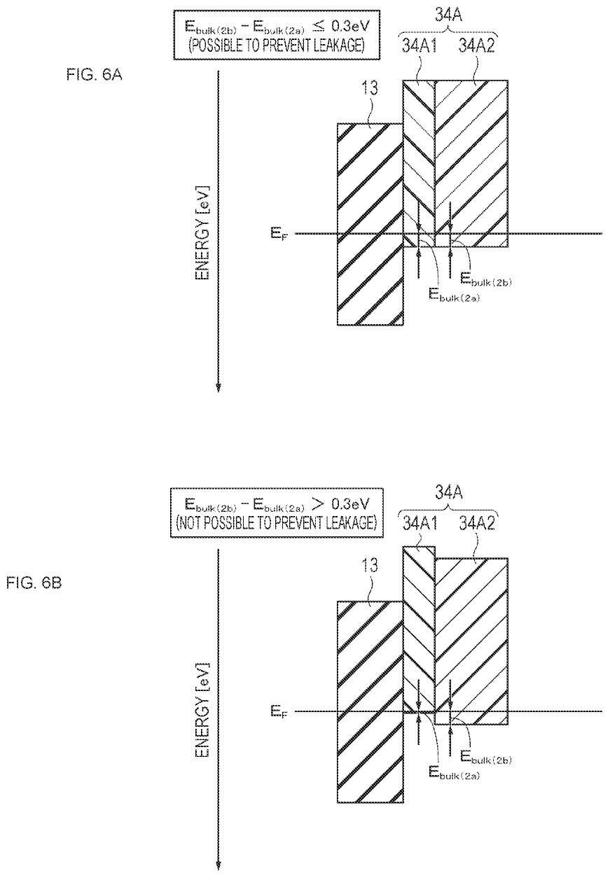

FIG. 6A is a diagram illustrating an example of an energy diagram of the insulating layer 13, the first hole transport layer 34A1, and the second hole transport layer 34A2. An energy level E_{bulk(2a)} of a bulk of the first hole transport layer 34A1 and an energy level E_{bulk(2b)} of a bulk of the second hole transport layer 34A2 satisfy the following Formula (2).

0≤E_{bulk(2b)}−E_{bulk(2a)}≤0.3 eV (2)

The energy level E_{bulk(2a)} is measured as follows described above. Each layer formed on the first surface of the organic EL layer 34 is removed. After the removal, the organic EL layer 34 is etched from the interface between the insulating layer 13 and the first hole transport layer 34A1 to a position of 10 nm toward the first hole transport layer 34A1 side by ion sputtering. Subsequently, the energy level (HOMO) of the surface exposed by etching is measured by XPS, and the measured value is defined as the energy level E_{bulk(2a)}. The measurement conditions of XPS are similar to those of the method of measuring the energy level E_{interface(1)} in the first embodiment.

The energy level E_{bulk(2b)} is measured as follows described above. Each layer formed on the first surface of the organic EL layer 34 is removed. After the removal, the organic EL layer 34 is etched from the interface between the first hole transport layer 34A1 and the second hole transport layer 34A2 to a position of 10 nm toward the second hole transport layer 34A2 side by ion sputtering. Subsequently, the energy level (HOMO) of the surface exposed by etching is measured by XPS, and the measured value is defined as the energy level E_{bulk(2b)}. The measurement conditions of XPS are similar to those of the method of measuring the energy level E_{interface(1)} in the first embodiment.

### [Operation and Effect]

As described above, in the display device 30 according to the second embodiment, as illustrated in FIG. 6A, since the energy level E_{bulk(2a)} and the energy level E_{bulk(2b)} satisfy the above Formula (2), it is possible to prevent leakage of a drive current between the adjacent subpixels 100. On the other hand, as illustrated in FIG. 6B, in a case where the energy level E_{bulk(2a)} and the energy level E_{bulk(2b)} do not satisfy the above Formula (2), leakage of the drive current between the adjacent subpixels 100 cannot be prevented.

### 3 Third Embodiment

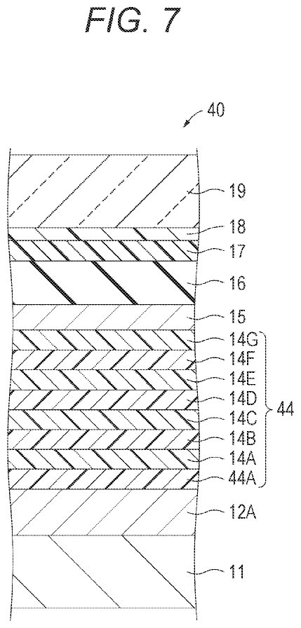

FIG. 7 is a cross-sectional view illustrating an example of a configuration of a display device 40 according to a third embodiment of the present disclosure. The display device 40 is different from the display device 10 according to the first embodiment in that an organic EL layer 44 is provided instead of the organic EL layer 14 (see FIG. 2). Note that, in the third embodiment, same reference numerals are given to parts similar to those of the first embodiment, and the description thereof will be omitted.

The organic EL layer 44 is different from the organic EL layer 14 in the first embodiment in further including a hole injection layer 44A. The hole injection layer 44A is provided between the first electrode layer 12 (see FIG. 2) and the hole transport layer 14A, and is adjacent to the first electrode layer 12 and the insulating layer 13. The hole injection layer 31A is for enhancing hole injection efficiency into each of the light emitting layers 14B, 14D, and 14E and preventing leakage. The hole injection layer 44A includes, for example, hexaazatriphenylene carbonitrile (HATCN) or the like.

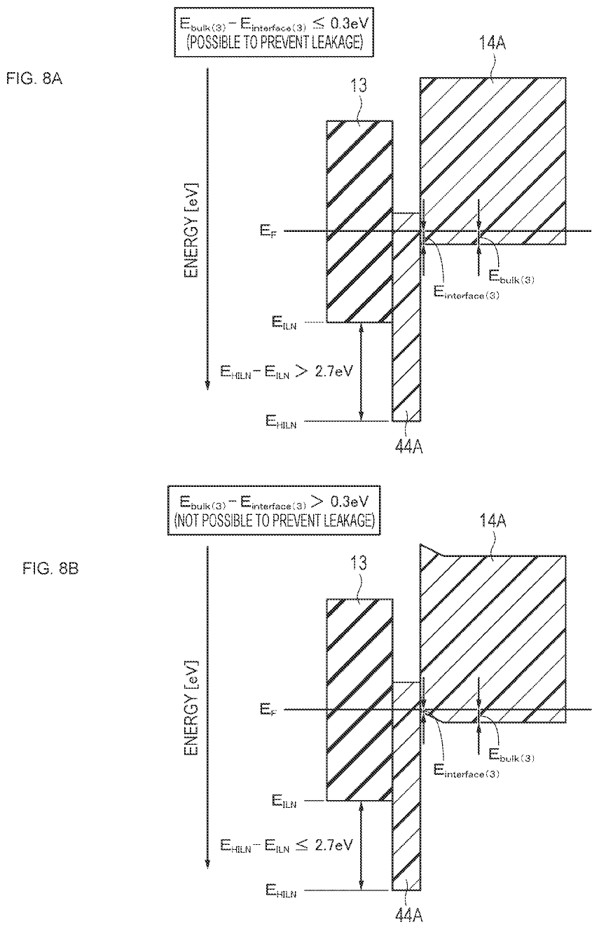

FIG. 8A is a diagram illustrating an example of an energy diagram of the insulating layer 13, the hole injection layer 44A, and the hole transport layer 14A. An energy level E_{interface(3)} at the interface between the hole injection layer 44A and the hole transport layer 14A and an energy level E_{bulk(3)} in the bulk of the hole transport layer 14A satisfy the following Formula (3).

0≤E_{bulk(3)}−E_{interface(3)}≤0.3 eV (3)

The energy level E_{interface(3)} described above is measured as follows. Each layer formed on the first surface of the organic EL layer 44 is removed. After the removal, the organic EL layer 44 is etched from the interface between the hole injection layer 44A and the hole transport layer 14A to a position of 2 nm toward the hole transport layer 14A side by ion sputtering. Subsequently, the energy level (HOMO) of the surface exposed by etching is measured by XPS, and the measured value is defined as the energy level E_{interface(3)}. The measurement conditions of XPS are similar to those of the method of measuring the energy level E_{interface(1)} in the first embodiment.

The energy level E_{bulk(3)} described above is measured as follows. Each layer formed on the first surface of the organic EL layer 44 is removed. After the removal, the organic EL layer 44 is etched from the interface between the hole injection layer 44A and the hole transport layer 14A to a position of 10 nm toward the hole transport layer 14A side by ion sputtering. Subsequently, the energy level (HOMO) of the surface exposed by etching is measured by XPS, and the measured value is defined as the energy level E_{bulk(3)}. The measurement conditions of XPS are similar to those of the method of measuring the energy level E_{interface(1)} described above.

In a case where the hole injection layer 44A and the insulating layer 13 include nitrogen, the bond energy E_{HILN} of N1s in the hole injection layer 44A and the bond energy E_{ILN} of N1s in the insulating layer 13 preferably satisfy the following Formula (3a).

2.7 eV<E_{HILN}−E_{ILN} (3a)

The bond energy E_{HILN} described above is measured as follows. Each layer formed on the first surface of the organic EL layer 44 is removed. After the removal, the organic EL layer 44 is etched by ion sputtering to expose the surface (first surface) of the hole injection layer 44A. Subsequently, the exposed surface of the hole injection layer 44A is subjected to XPS measurement to acquire an XPS spectrum. From this XPS spectrum, a bond energy value at the vertex of the peak derived from the N1s orbit of the hole injection layer 44A is obtained and defined as bond energy E_{HILN}.

The bond energy E_{ILN} described above is measured as follows. Each layer formed on the first surface of the organic EL layer 44 is removed. After the removal, next, the organic EL layer 44 is etched by ion sputtering to expose the surface (first surface) of the insulating layer 13. Next, the exposed surface of the insulating layer 13 is subjected to XPS measurement to acquire an XPS spectrum. From this XPS spectrum, a bond energy value at the vertex of the peak derived from the N1s orbit of the insulating layer 13 is obtained and defined as bond energy E_{ILN}. Note that the measurement conditions of XPS are similar to those of the method of measuring the energy level E_{interface(1)} described above.

### [Operation and Effect]

As described above, in the display device 40 according to the third embodiment, as illustrated in FIG. 8A, since the energy level E_{interface(3)} and the energy level E_{bulk(3)} satisfy the above Formula (3), it is possible to prevent leakage of a drive current between the adjacent subpixels 100. On the other hand, as illustrated in FIG. 8B, in a case where the energy level E_{interface(3)} and the energy level E_{bulk(3)} do not satisfy the above Formula (3), leakage of the drive current between the adjacent subpixels 100 cannot be prevented.

### 4 Fourth Embodiment

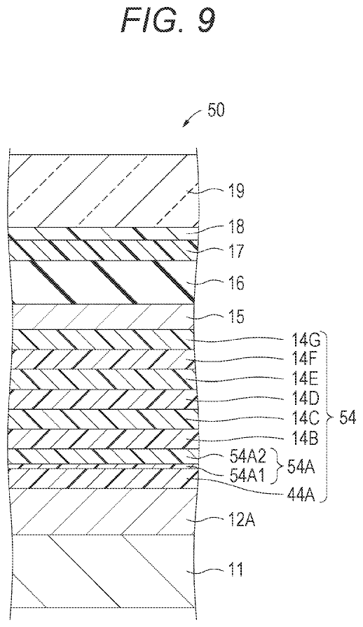

FIG. 9 is a cross-sectional view illustrating an example of a configuration of a display device 50 according to a fourth embodiment of the present disclosure. The display device 50 is different from the display device 40 according to the third embodiment in that an organic EL layer 54 is provided instead of the organic EL layer 14 (see FIG. 7). Note that, in the fourth embodiment, same reference numerals are given to parts similar to those of the third embodiment, and the description thereof will be omitted.

The organic EL layer 54 is different from the organic EL layer 44 in the third embodiment in including a hole transport layer 54A having a two-layer structure instead of the hole transport layer 14A having a single-layer structure. The hole transport layer 54A includes a first hole transport layer 54A1 and a second hole transport layer 54A2. The first hole transport layer 54A1 is adjacent to the hole injection layer 44A. The second hole transport layer 54A2 is adjacent to the red light emitting layer 14B.

FIG. 10A is a diagram illustrating an example of an energy diagram of the insulating layer 13, the hole injection layer 44A, the first hole transport layer 54A1, and the second hole transport layer 54A2. An energy level E_{bulk(4a)} of a bulk of the first hole transport layer 54A1 and an energy level E_{bulk(4b)} of a bulk of the second hole transport layer 54A2 satisfy the following Formula (4).

0≤E_{bulk(4b)}−E_{bulk(4a)}≤0.3 eV (4)

The energy level E_{bulk(4a)} described above is measured as follows. Each layer formed on the first surface of the organic EL layer 44 is removed. After the removal, the organic EL layer 54 is etched from the interface between the hole injection layer 44A and the first hole transport layer 54A1 to a position of 10 nm toward the first hole transport layer 34A1 side by ion sputtering. Subsequently, the energy level (HOMO) of the surface exposed by etching is measured by XPS, and the measured value is defined as the energy level E_{bulk(4a)}. The measurement conditions of XPS are similar to those of the method of measuring the energy level E_{interface(1)} described above.

The energy level E_{bulk(4b)} described above is measured as follows. Each layer formed on the first surface of the organic EL layer 44 is removed. After the removal, the organic EL layer 54 is etched from the interface between the first hole transport layer 54A1 and the second hole transport layer 54A2 to a position of 10 nm toward the second hole transport layer 54A2 side by ion sputtering. Subsequently, the energy level (HOMO) of the surface exposed by etching is measured by XPS, and the measured value is defined as the energy level E_{bulk(4b)}. The measurement conditions of XPS are similar to those of the method of measuring the energy level E_{interface(1)} in the first embodiment.

### [Operation and Effect]

As described above, in the display device 50 according to the fourth embodiment, as illustrated in FIG. 10A, since the energy level E_{bulk(4a)} and the energy level E_{bulk(4b)} satisfy the above Formula (4), it is possible to prevent leakage of a drive current between the adjacent subpixels 100. On the other hand, as illustrated in FIG. 10B, in a case where the energy level E_{bulk(4a)} and the energy level E_{bulk(4b)} do not satisfy the above Formula (4), leakage of the drive current between the adjacent subpixels 100 cannot be prevented.

### 5 Modification Example

### Modification Example 1

In the first to fourth embodiments, an example in which the organic EL layers 14, 34, 44, and 54 include a single-layer light emitting unit has been described, but the organic EL layers may have a stack structure including a plurality of stacked light emitting units. In this case, a charge generation layer is sandwiched between adjacent light emitting units.

### Modification Example 2

In the second and fourth embodiments, an example has been described in which the hole transport layers 34A and 54A have a stacked structure including two layers, but may have a stacked structure including three or more layers.

### Modification Example 3

In the first to fourth embodiments, an example of adjusting the band bending of the hole transport layers 14A, 34A, and 54A by adjusting the process gas flow ratio at the time of forming the insulating layer 13 has been described, but the method of adjusting the band bending is not limited thereto.

The band bending may be controlled by adjusting film formation conditions of the insulating layer 13 other than the process gas flow ratio. Specifically, for example, the hydrogen content in the insulating layer 13 may be controlled. Alternatively, p-type doping or n-type doping may be performed on the insulating layer 13 to change a donor level or an acceptor level in the insulating layer 13.

Constituent materials of the hole transport layers 14A, 34A, and 54A may be selected to control the band bending. Specifically, for example, a hole transport material having a Fermi level (HOMO, LUMO (Lowest Unoccupied Molecular Orbital)) such that the band bending is 0.3 eV or less may be used. In a case of the hole transport layer 34A having a stacked structure including two layers, as the hole transport material of the first hole transport layer 34A1 and the second hole transport layer 34A2, one having a Fermi level (HOMO, LUMO) such that the HOMO energy difference is 0.3 eV or less in a state where the first hole transport layer 34A1 and the second hole transport layer 34A2 are joined may be used. Also in a case of the hole transport layer 54A having a stacked structure including two layers, the hole transport material of each layer may be selected similarly to a case of the hole transport layer 34A having the stacked structure described above.

### Modification Example 4

In the first to fourth embodiments, an example in which the method using the white light emitting element and the color filter 17 is used as a coloring method in the display device 10 has been described, but the coloring method is not limited thereto. For example, a method of extracting three-color light (red light, green light, and blue light) by a resonator structure may be used, or a method of enhancing color purity by using the color filter 17 and the resonator structure in combination may be used.

### 6 Application Example

### (Electronic Device)

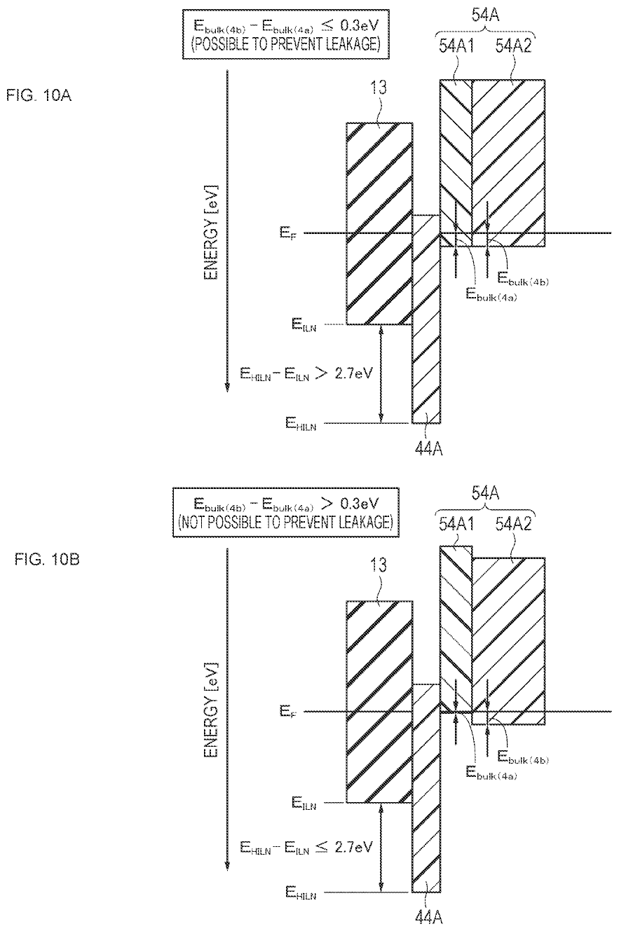

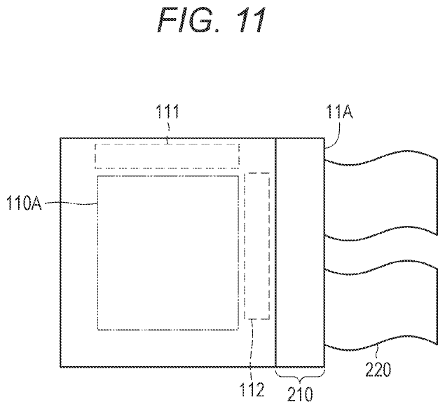

The display devices 10, 30, 40, and 50 (hereinafter referred to as a “display devices 10 and so on”) according to the above-described first to fourth embodiments and the modification examples thereof can be used for various electronic devices. The display devices 10 and so on are incorporated in various electronic devices, for example, as a module as illustrated in FIG. 11. In particular, high resolution such as an electronic viewfinder or a head-mounted display of a video camera or a single-lens reflex camera is required, and is suitable for those that are enlarged and used near eyes. This module has a region 210 exposed without being covered with the counter substrate 19 or the like on one short side of the drive substrate 11, and external connection terminals (not illustrated) are formed in this region 210 by extending wirings of the signal line drive circuit 111 and the scanning line drive circuit 112. A flexible printed circuit (FPC) 220 for inputting and outputting signals may be connected to the external connection terminals.

### Specific Example 1

FIGS. 12A and 12B illustrate an example of an external appearance of a digital still camera 310. The digital still camera 310 is of a lens interchangeable single lens reflex type, and includes an interchangeable imaging lens unit (interchangeable lens) 312 substantially at the center in front of a camera body portion (camera body) 311, and a grip portion 313 to be held by a photographer on a front left side.

A monitor 314 is provided at a position shifted to the left from the center of a rear surface of the camera body 311. An electronic viewfinder (eyepiece window) 315 is provided above the monitor 314. By looking through the electronic viewfinder 315, the photographer can visually confirm a light image of the subject guided from the imaging lens unit 312 and determine a picture composition. As the electronic viewfinder 315, any of the display devices 10 and so on can be used.

### Specific Example 2

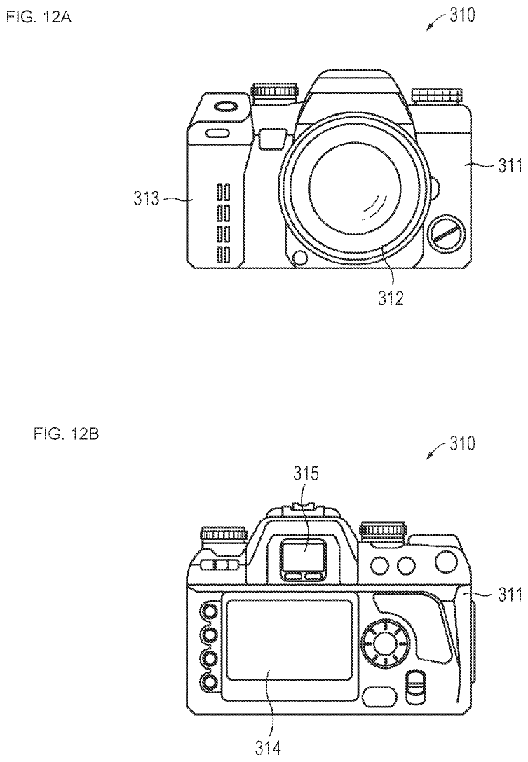

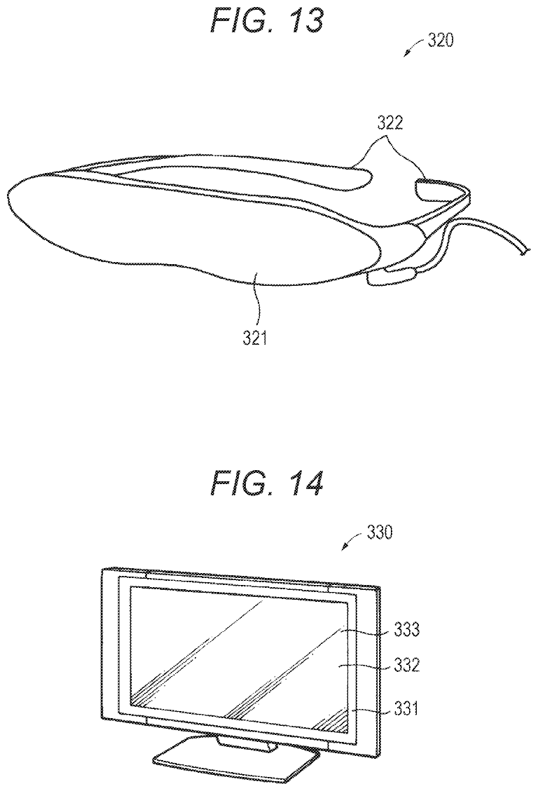

FIG. 13 illustrates an example of an external appearance of a head mounted display 320. The head mounted display 320 includes, for example, ear hooking portions 322 to be worn on the head of the user on both sides of a glass-shaped display unit 321. As the display unit 321, any one of the display devices 10 and so on can be used.

### Specific Example 3

FIG. 14 illustrates an example of an external appearance of a television apparatus 330. The television apparatus 330 includes, for example, a video display screen unit 331 including a front panel 332 and a filter glass 333, and the video display screen unit 331 includes any of the display devices 10 and so on.

### EXAMPLES

Hereinafter, the present disclosure will be specifically described with reference to examples, but the present disclosure is not limited to only these examples.

### Examples 1 and 2 and Comparative Examples 1 and 2

First, a metal layer (Al alloy layer) and a metal oxide layer (ITO layer) were sequentially formed on the first surface of the drive substrate by the sputtering method, and then the metal layer and the metal oxide layer were patterned using the photolithography technique and an etching technique. Thus, a first electrode layer having a plurality of electrodes was formed.

Next, an insulating layer (SiN layer) having an average thickness of 40 nm was formed on the first surface of the drive substrate by the CVD method. At this time, SiH₄ gas and NH₃ gas were used as process gases. Furthermore, the flow ratio between the SiH₄ gas and the NH₃ gas was adjusted so that E_{HILN} E_{ILN} had values indicated in Table 1. Thus, a layer having a fixed charge was simultaneously formed on the first surface of the insulating layer. The larger E_{HILN} E_{ILN}, the smaller the amount of the fixed charge.

Next, an opening was formed in a portion of the insulating layer located on the first surface of each electrode by the photolithography technique and the dry etching technique. Next, an organic EL layer was formed by stacking a hole injection layer (HATCN), a hole transport layer (α-NPD), a light emitting layer, and an electron transport layer on the electrode and the insulating layer by the vapor deposition method. Next, a second electrode layer (MgAg alloy layer) was formed on the first surface of the organic EL layer. Thus, an intended display device was obtained.

(E_{HILN}−E_{ILN})

E_{HILN} and E_{ILN} of the display devices of Examples 1 and 2 and Comparative Examples 1 and 2 obtained as described above were measured as in the third embodiment, and E_{HILN}−E_{ILN} was obtained. The results are indicated in Table 1.

### (Leakage Current Between Subpixels)

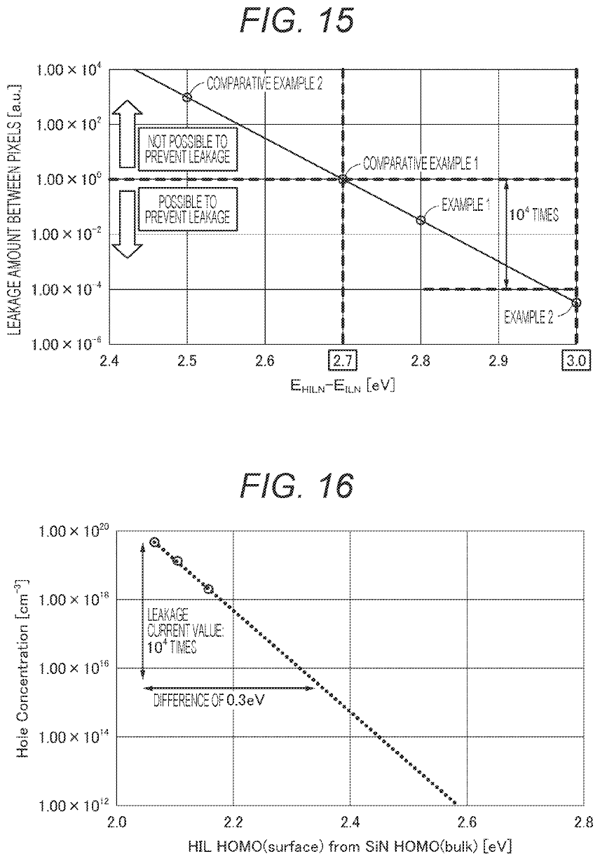

Leakage currents between subpixels of the display devices of Examples 1 and 2 and Comparative Examples 1 and 2 obtained as described above were measured. The results are indicated in Table 1. Furthermore, the relationship between E_{HILN}−E_{ILN} and the leakage currents between the subpixels is illustrated in FIG. 15.

Table 1 indicates evaluation results of the display devices of Examples 1 and 2 and Comparative Examples 1 and 2.

TABLE 1

| | | Leakage amount |
|---|---|---|
| | E_{HILN} − E_{ILN} | between pixels |
| | [eV] | [a.u.] |
| Example 1 | 2.8 | 0.04 |
| Example 2 | 3.0 | 3.9 × 10⁻⁵ |
| Comparative Example 1 | 2.7 | 1.0 |
| Comparative Example 2 | 2.5 | 970 |

Table 1 and FIG. 15 indicate the following.

The leakage currents between the subpixels depend on the value of E_{HILN}−E_{ILN}. Specifically, when leakage is determined with the leakage amount (=1.0) of Comparative Example 1 as a reference value, in a case where 2.7 eV<E_{HILN}−E_{ILN}, a leakage current flowing between the subpixels can be prevented. On the other hand, in a case where E_{HILN}−E_{ILN} 2.7 eV, it is difficult to prevent the leakage current from flowing between the subpixels.

### [Simulation]

By device simulation, the relationship between the difference between the HOMO of the hole injection layer and the HOMO of the insulating layer and the hole concentration (leakage amount) between the subpixels was obtained. The results are indicated in FIG. 16. Note that the hole concentration and the hole leakage current value have a proportional relationship.

Conditions of the device simulation were set as follows. Note that a state in which the display device is driven was simulated in the device simulation.
Device simulator: Atlas manufactured by Silvaco Inc.
Hole transport layer (HTL): film thickness 50 nm, LUMO=1.5, HOMO=5.5 [eV]
Hole injection layer (HIL): film thickness 2 nm, LUMO=HOMO=9.8 [eV]
Insulating layer (SiN): film thickness 30 nm, EA (electron affinity)=2.6 [eV], Bg=4.7 [eV]
Electrode
Upper electrode (cathode): ITO WF (work function)=5.0 [eV]
Lower electrode (anode): ITO WF=5.0 [eV]
Voltage
Upper electrode=0.0 [V], lower electrode=0.0 to 5.0 [V]

From the result of the device simulation described above (see FIG. 16), it can be seen that the leakage amount changes by 4 times when the difference between the HOMO of the hole injection layer and the HOMO of the insulating layer changes by eV. The change in the difference 0.3 eV between the HOMO of the hole injection layer and the HOMO of the insulating layer can be considered to have the same meaning as the change in the difference between E_{HILN} and E_{ILN} by 0.3 eV when it is considered that the energy difference between the inner shell energy and the HOMO does not change regardless of the bonding state. Thus, it is considered that there is a difference of 10⁴ times in the leakage current amount between the subpixels between a case where the difference between E_{HILN} and E_{ILN} is 3.0 eV (Example 2) and a case where the difference between E_{HILN} and E_{ILN} is 2.7 eV (Comparative Example 1) as described above (see FIG. 15).

The band bending amount in which the difference in leakage amount as described above appears is calculated as follows.

I=envS

(I: current, e: charge of one free electron, n: number density of free electrons, and vS: volume corresponding to movement of free electron)

In a case where the above formula is used, the current I can be expressed as follows.

I∝n∝exp(−ΔE/kT)

(ΔE: energy difference, k: Boltzmann constant, and T: absolute temperature)

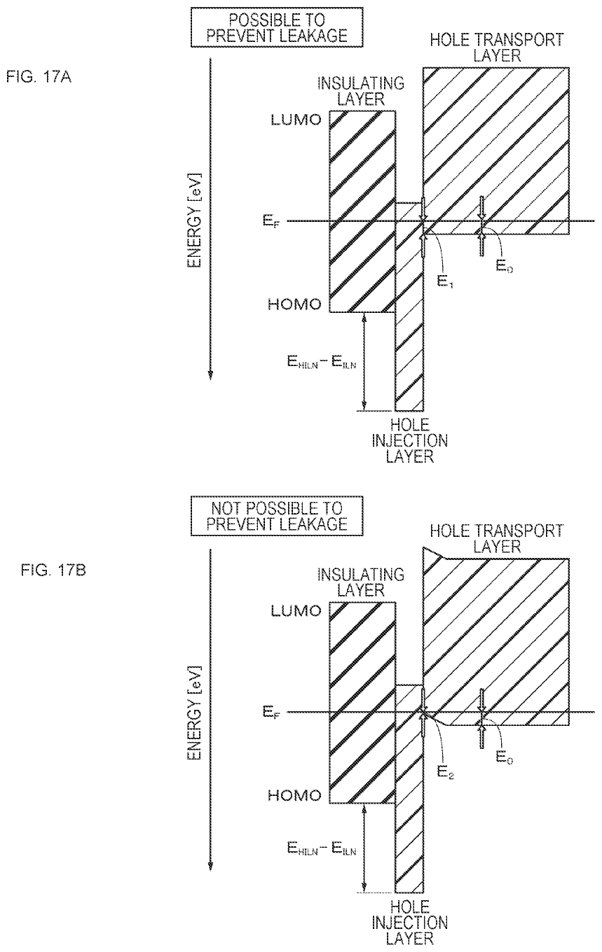

Using the energy values E₀, E₁, and E₂ defined in FIG. 17, the current I₁ when the leakage current is prevented and the current I₂ when the leakage current is not prevented are expressed as follows.

I₁∝exp(−(E₀−E₁)/kT)

I₂∝exp(−(E₀−E₂)/kT)

Since there is a difference of 10⁴ times between the current I₁ and the current I₂, the difference is expressed as follows.

I₁/I₂=10⁴=exp(−((E₀−E₁)+(E₀−E₂))/kT)=exp((E₁−E₂)/kT)

When the above formula is solved by substituting values for k and T, E₁−E₂ is expressed as follows.

E₁−E₂=0.3 eV

In a case where the leakage current is prevented, assuming that E_{bulk}−E_{interface}=0 (E₀−E₁=0), E₁−E₂ is expressed as follows.

E₁−E₂=E₀−E₂=0.3 eV

Therefore, the band bending amount in a state where 10⁴ times the leakage current flows from the state where the leakage current is prevented is 0.3 eV.

Although the first to fourth embodiments of the present disclosure and modification examples thereof have been specifically described above, the present disclosure is not limited to the first to fourth embodiments described above and their modification examples, and various modifications based on the technical idea of the present disclosure are possible.

For example, the configurations, methods, steps, shapes, materials, numerical values, and the like given in the first to fourth embodiments described above and the modification examples thereof are merely examples, and different configurations, methods, steps, shapes, materials, numerical values, and the like may be used as necessary.

The configurations, methods, steps, shapes, materials, numerical values, and the like of the above-described first to fourth embodiments and the modifications thereof can be combined with each other without departing from the gist of the present disclosure.

The materials exemplified in the above-described first to fourth embodiments and the modification examples thereof can be used alone or in combination of two or more unless otherwise specified.

Further, the present disclosure can also employ the following configurations.

(1)

A display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer, the hole transport layer being adjacent to the insulating layer, and
an energy level E_{interface(1)} at an interface between the insulating layer and the hole transport layer and an energy level E_{bulk(1)} in a bulk of the hole transport layer satisfy following Formula (1).

0≤E_{bulk(1)}−E_{interface(1)}≤0.3 eV (1)

(2)

A display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer,
the hole transport layer includes at least a first hole transport layer and a second hole transport layer, the first hole transport layer being adjacent to the insulating layer, and
an energy level E_{bulk(2a)} of a bulk of the first hole transport layer and an energy level E_{bulk(2b)} of a bulk of the second hole transport layer satisfy following Formula (2).

0≤E_{bulk(2b)}−E_{bulk(2a)}≤0.3 eV (2)

(3)

A display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer and a hole injection layer, the hole injection layer being adjacent to the insulating layer, and
an energy level E_{interface(3)} at an interface between the hole injection layer and the hole transport layer and an energy level E_{bulk(3)} in a bulk of the hole transport layer satisfy following Formula (3).

0≤E_{bulk(3)}−E_{interface(3)}≤0.3 eV (3)

(4)

A display device, including:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, in which
the electroluminescence layer includes a hole transport layer and a hole injection layer, the hole injection layer being adjacent to the insulating layer,
the hole transport layer includes at least a first hole transport layer and a second hole transport layer, the first hole transport layer being adjacent to the hole injection layer, and
an energy level E_{bulk(4a)} of a bulk of the first hole transport layer and an energy level E_{bulk(4b)} of a bulk of the second hole transport layer satisfy following Formula (4).

0≤E_{bulk(4b)}−E_{bulk(4a)}≤0.3 eV (4)

(5)

The display device according to (3) or (4), in which
the hole injection layer and the insulating layer include nitrogen, and
a bond energy E_{HILN} of Nis in the hole injection layer and a bond energy E_{ILN} of Nis in the insulating layer satisfy following Formula (3a).

2.7 eV<E_{HILN}−E_{ILN} (3a)

(6)

The display device according to (5), in which
the hole injection layer includes hexaazatriphenylene carbonitrile, and
the insulating layer includes silicon nitride.

(7)

The display device according to any one of (1) to (6), in which
the electroluminescence layer is provided over the plurality of electrodes.

(8)

An electronic device including the display device according to any one of (1) to (7).

### REFERENCE SIGNS LIST

10, 30, 40, 50 Display device
11 Drive substrate
12 First electrode layer
12A Electrode
13 Insulating layer
13A Opening
14, 34, 44, 54 Organic electroluminescence layer
14A, 34A, 54A Hole transport layer
14B Red light emitting layer
14C Light emission separation layer
14D Blue light emitting layer
14E Green light emitting layer
14F Electron transport layer
14G Electron injection layer
15 Second electrode layer
16 Protective layer
17 Color filter
17R Red filter
17G Green filter
17B Blue filter
17BM Light shielding layer
18 Filling resin layer
19 Counter substrate
20 Light emitting element
34A1, 54A1 First hole transport layer
34A2, 54A2 Second hole transport layer
44A Hole injection layer
100R, 100G, 100B Subpixel
110A Display region
110B Peripheral region
111 Signal line drive circuit
111A Signal line
112 Scanning line drive circuit
112A Scanning line
310 Digital still camera (electronic device)
320 Head mounted display (electronic device)
330 Television apparatus (electronic device)

1. A display device, comprising:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, wherein
the electroluminescence layer includes a hole transport layer, the hole transport layer being adjacent to the insulating layer, and
an energy level E_{interface(1)} at an interface between the insulating layer and the hole transport layer and an energy level E_{bulk(1)} in a bulk of the hole transport layer satisfy following Formula (1).
0≤E_{bulk(1)}−E_{interface(1)}≤0.3 eV (1)

2. A display device, comprising:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, wherein
the electroluminescence layer includes a hole transport layer,
the hole transport layer includes at least a first hole transport layer and a second hole transport layer, the first hole transport layer being adjacent to the insulating layer, and
an energy level E_{bulk(2a)} of a bulk of the first hole transport layer and an energy level E_{bulk(2b)} of a bulk of the second hole transport layer satisfy following Formula (2).
0≤E_{bulk(2b)}−E_{bulk(2a)}≤0.3 eV (2)

3. A display device, comprising:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, wherein
the electroluminescence layer includes a hole transport layer and a hole injection layer, the hole injection layer being adjacent to the insulating layer, and
an energy level E_{interface(3)} at an interface between the hole injection layer and the hole transport layer and an energy level E_{bulk(3)} in a bulk of the hole transport layer satisfy following Formula (3).
0≤E_{bulk(3)}−E_{interface(3)}≤0.3 eV (3)

4. A display device, comprising:
a first electrode layer having a plurality of electrodes arranged two-dimensionally;
a second electrode layer provided to face the first electrode layer;
an electroluminescence layer provided between the first electrode layer and the second electrode layer; and
an insulating layer provided between the electrodes adjacent to each other, wherein
the electroluminescence layer includes a hole transport layer and a hole injection layer, the hole injection layer being adjacent to the insulating layer,
the hole transport layer includes at least a first hole transport layer and a second hole transport layer, the first hole transport layer being adjacent to the hole injection layer, and
an energy level E_{bulk(4a)} of a bulk of the first hole transport layer and an energy level E_{bulk(4b)} of a bulk of the second hole transport layer satisfy following Formula (4).
0≤E_{bulk(4b)}−E_{bulk(4a)}≤0.3 eV (4)

5. The display device according to claim 3, wherein
the hole injection layer and the insulating layer include nitrogen, and
a bond energy E_{HILN} of Nis in the hole injection layer and a bond energy E_{ILN} of Nis in the insulating layer satisfy following Formula (3a).
2.7 eV<E_{HILN}−E_{ILN} (3a)

6. The display device according to claim 5, wherein
the hole injection layer includes hexaazatriphenylene carbonitrile, and
the insulating layer includes silicon nitride.

7. The display device according to claim 1, wherein
the electroluminescence layer is provided over the plurality of electrodes.

8. An electronic device comprising the display device according to claim 1.
